(19) United States
(12) Patent Application Publication
(10) Pub. No.: US 2007/0284662 A1
(43) Pub. Date: Dec. 13, 2007

(54) MICROELECTRONIC STRUCTURE INCLUDING HIGH CURRENT DENSITY RESISTOR

(75) Inventors: Anil K. Chinthakindi, Wappingers Falls, NY (US); Baozhen Li, South Burlington, VT (US); Gerald R. Matusiewicz, Poughkeepsie, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/423,232

(22) Filed: Jun. 9, 2006

(51) Int. Cl. H01L 27/12

(52) U.S. Cl. 257/350

(57) ABSTRACT

A microelectronic structure and a method for fabricating the microelectronic structure include a resistor located and formed over a substrate. A conductor contact layer contacts the resistor. A maximum length of the conductor contact layer is determined using a Blech constant to avoid electromigration of a conductor material that comprises the conductor contact layer.

### BACKGROUND

1. Field of the Invention

The invention relates generally to resistors within microelectronic structures. More particularly, the invention relates to high performance resistors within microelectronic structures.

2. Description of the Related Art

In addition to transistors, capacitors and diodes, microelectronic structures including, in particular, semiconductor structures, often include resistors. Resistors within microelectronic structures may be used for functions that include resistive load functions, as well as signal modification functions.

Recent advances in microelectronic circuits provide a need for high current density resistors within microelectronic circuits. High current density within a resistor is generally understood to be in a range from about 0.5 to about 2.0 milliamp per micron resistor width (i.e., the width is intended as a direction perpendicular to a length direction having opposite ends at which contacts are made). High current density resistors are often used in application specific integrated circuits. High current density resistors may also be used in applications that include power circuits.

The advent of high current density resistors in microelectronic structures also creates concerns with respect to thermal and electrical instability of structures that surround the high current density resistors. Such thermal or electrical instability may result from a high current density within electrical interconnects that connect a high current density resistor to other electrical circuit elements. Alternatively, but not limiting, such electrical instability may result from heat dissipation within a high current density resistor.

Resistors which may be used in high current applications are known in the microelectronic fabrication art.

For example, Arcidiacono, et al., in U.S. Pat. No. 4,251,326 and U.S. Pat. No. 4,410,867 teaches use of tantalum nitride as a resistor material in resistor-capacitor networks.

As microelectronic fabrication technology continues to advance and microelectronic structure dimensions continue to decrease, it becomes increasingly important to fabricate high current density resistors within microelectronic structures. Desirable are high current density resistors and high current density resistor structures that are thermally and electrically stable.

### SUMMARY OF THE INVENTION

The invention provides microelectronic structures and methods for fabricating microelectronic structures. The microelectronic structures and methods for fabrication thereof include high current density resistors.

A microelectronic structure in accordance with the invention includes a resistor located over a substrate. The microelectronic structure also includes a conductor contact layer contacting the resistor. A maximum length of the conductor contact layer is determined using a Blech constant to avoid electromigration of a conductor material that comprises the conductor contact layer.

A method for fabricating a microelectronic structure in accordance with the invention includes forming a resistor located over a substrate. The method also includes forming a conductor contact layer contacting the resistor. The conductor contact layer has a maximum length determined using a Blech constant to avoid electromigration of a conductor material that comprises the conductor contact layer.

### BRIEF DESCRIPTION OF THE DRAWINGS

The objects, features and advantages of the invention are understood within the context of the Description of the Preferred Embodiment as set forth below. The Description of the Preferred Embodiment is understood within the context of the accompanying drawings, that form a material part of this disclosure, wherein:

FIG. 1 to FIG. 10 show a series of schematic cross-sectional diagrams illustrating the results of progressive stages in fabricating a semiconductor structure in accordance with an embodiment of the invention.

FIG. 11 shows a schematic cross-sectional diagram of a semiconductor structure in accordance with another embodiment of the invention.

### DESCRIPTION OF THE PREFERRED EMBODIMENTS

The invention, which comprises a microelectronic structure (i.e., generally a semiconductor structure) that in turn comprises a resistor structure, is understood within the context of the description provided below. The description is understood within the context of the accompanying drawings, as described above. The drawings are intended for illustrative purposes, and as such the drawings are not necessarily drawn to scale.

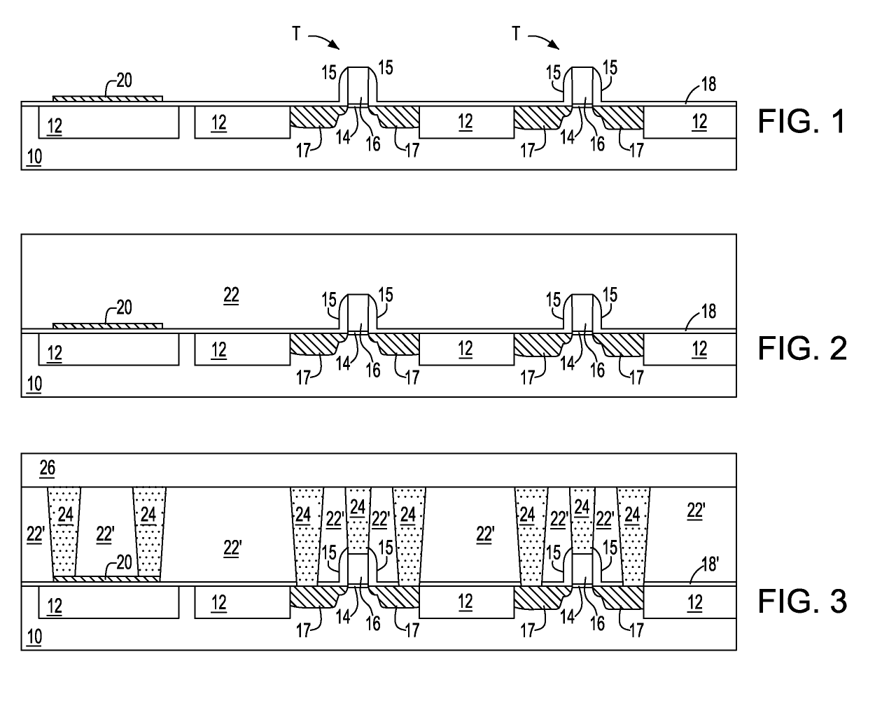

FIG. 1 to FIG. 10 show a series of schematic cross-sectional diagrams illustrating the results of progressive stages in fabricating a semiconductor structure in accordance with an embodiment of the invention. This embodiment of the invention comprises a first embodiment of the invention.

FIG. 1 shows a semiconductor substrate 10. Isolation regions 12 are located within semiconductor substrate 10 and separate active regions therein. Transistors T are located within the active regions separated by the isolation regions 12. Capping layer 18 caps each of the transistors, and capping layer 18 also serves as a base for resistor 20 located over isolation region 12.

The semiconductor substrate 10 and remaining structures designated above may comprise materials and have dimensions that are conventional in the semiconductor fabrication art. The semiconductor substrate 10 and remaining structures designated above may also be formed using methods that are conventional in the semiconductor fabrication art.

The semiconductor substrate 10 comprises a semiconductor material. Non-limiting examples of semiconductor materials include silicon, germanium, silicon-germanium alloy, silicon carbide, silicon-germanium carbide alloy and compound semiconductor materials. Non-limiting examples of compound semiconductor materials include gallium arsenide, indium arsenide and indium phosphide semiconductor materials.

The semiconductor substrate 10 may comprise a bulk semiconductor material as is generally illustrated within the schematic cross-sectional diagram of FIG. 1. Alternatively, the semiconductor substrate 10 may comprise a semiconductor-on-insulator substrate or a hybrid orientation substrate. A semiconductor-on-insulator substrate comprises a base semiconductor substrate, a buried dielectric layer located thereupon and a surface semiconductor layer located further thereupon. A hybrid orientation substrate comprises multiple semiconductor regions having different crystallographic orientations. Semiconductor-on-insulator substrates and hybrid orientation substrates may be formed using any of several methods. Non-limiting examples include layer transfer methods, other laminating methods and separation by implantation of oxygen (SIMOX) methods.

The isolation regions 12 comprise isolation materials that are typically dielectric isolation materials. The dielectric isolation materials may comprise any of several dielectric materials. Non-limiting examples of dielectric materials include oxides, nitrides and oxynitrides of silicon. Oxides, nitrides and oxynitrides of other elements are not excluded. Also contemplated are laminates and composites of the foregoing dielectric isolation materials. Similarly, the dielectric isolation materials may also be a crystalline material or a non-crystalline material. The isolation regions 12 may be formed using any of several methods. Non-limiting examples include thermal or plasma oxidation or nitridation methods, chemical vapor deposition methods (including atomic layer chemical vapor deposition methods) and physical vapor deposition methods (including sputtering methods). Typically, the isolation regions 12 comprise at least in part a silicon oxide dielectric material that has a thickness (i.e., trench depth) from about 2000 to about 6000 angstroms.

The transistors T comprise gate dielectrics 14. Gate electrodes 16 are located upon gate dielectrics 14. Spacer layers 15 adjoin sidewalls of gate electrodes 16. Source/drain regions 17 are located within the semiconductor substrate 10 and separated by channel regions located beneath the gate electrodes 16.

Each of the foregoing structures that comprise the transistors T may comprise materials and have dimensions that are conventional in the semiconductor fabrication art. Each of the foregoing structures that comprise the transistors T may be formed using methods that are conventional in the semiconductor fabrication art.

Gate dielectrics 14 may comprise generally conventional gate dielectric materials having a dielectric constant from about 4 to about 20, measured in vacuum. Non-limiting examples of these gate dielectric materials include silicon oxide, silicon nitride and silicon oxynitride gate dielectric materials. The gate dielectrics 14 may also comprise generally higher dielectric constant gate dielectric materials having a dielectric constant from about 20 to at least about 100, also measured in vacuum. Non-limiting examples of these gate dielectric materials include hafnium oxides, haffiium silicates, titanium oxides, lanthanum oxides, barium-strontium titanates (BSTs) and lead-zirconate titanates (PZTs). The gate dielectrics 14 may be formed using methods that are conventional in the semiconductor fabrication art. Non limiting examples include thermal or plasma oxidation or nitridation methods, chemical vapor deposition methods and physical vapor deposition methods. Typically, the gate dielectrics 14 comprise a thermal silicon oxide gate dielectric material that has a thickness from about 15 to about 50 angstroms.

The gate electrodes 16 may similarly comprise gate electrode materials that are conventional in the semiconductor fabrication art. Included, but not limiting, are certain metals, metal alloys, metal nitrides and metal silicides. Also included, but not limiting, are doped polysilicon and polycide gate electrode materials. The gate electrode materials may be deposited using methods that are appropriate to their material of composition. Non-limiting examples include plating methods, chemical vapor deposition methods and physical vapor deposition sputtering methods. Typically, the gate electrodes 16 comprise a metal gate material, a polycide gate material or a polysilicon gate material that has a thickness from about 2000 to about 5000 angstroms.

The spacer layers 15 (which are illustrated as plural layers in cross-section but are actually single layers that completely surround gate electrodes 16 in plan view) typically comprise dielectric spacer materials, although conductor spacer materials are also known. Dielectric spacer materials may comprise the same materials as the isolation regions 12. Conductor spacer materials may use the same materials as the gate electrodes 16. Typically, the spacers 15 comprise at least in part a dielectric spacer material. The spacers 15 are formed using a blanket layer deposition and anisotropic etchback method that is otherwise generally conventional in the semiconductor fabrication art.

The source/drain regions 17 comprise a dopant of polarity appropriate for a polarity of a transistor T desired to be formed. Typically, the source/drain regions 17 are formed using a two step ion implantation process. A first step within the two step ion implantation process uses the gate 16 as a mask absent the spacers 15 to form extension regions into the semiconductor substrate 10. A second step within the two step ion implantation process uses the gate electrode 16 and spacers 15 as a mask to form contact region portions of the source/drain regions 17 that incorporate the extension regions. Typically, the extension regions have a dopant concentrations from about 1e15 to about 1e16 dopant atoms per cubic centimeter and the contact regions have a dopant concentration from about 1e18 to about 1e21 dopant atoms per cubic centimeter.

Capping layer 18 typically comprises a dielectric capping material. Dielectric capping materials may be selected from the same group of materials as the isolation regions 12. The dielectric capping materials may also be deposited using the same methods as disclosed above for the isolation regions 12. Typically, the capping layer 18 has a thickness from about 200 to about 700 angstroms.

The resistor 20 comprises a resistive material, but the resistor 20 is not necessarily intended as a resistor in accordance with the invention. Typically the resistor 20 is a generally lower resistance resistor that may comprise a generally conventional resistive material, such as a polysilicon resistive material. Typically, the resistor 20 has a thickness from about 200 to about 2000 angstroms.

FIG. 2 shows a passivation layer 22 located upon the semiconductor structure of FIG. 1. The passivation layer 22 may comprise any of several passivation materials. The passivation materials may be selected from the same group of dielectric materials as the isolation regions 12. The passivation layer 22 may be formed using the same group of methods that are used for forming the isolation regions 12. Typically, the passivation layer 22 comprises at least in part a silicon oxide material that has a thickness from about 5000 to about 8000 angstroms.

FIG. 3 first shows a series of contact studs 24 located within a series of contact vias within the passivation layer 22 that is illustrated within the schematic cross-sectional diagram of FIG. 2, to thus form passivation layer 22′.

To obtain the semiconductor structure that is illustrated within the schematic cross-sectional diagram of FIG. 3 from the semiconductor structure whose schematic cross-sectional diagram is illustrated in FIG. 2, the passivation layer 22 is first patterned to form the passivation layer 22′. The passivation layer 22 is patterned to form the passivation layer 22′ while using photolithographic masking and etch methods that are otherwise generally conventional in the semiconductor fabrication art. With respect to etch methods, included are wet chemical etch methods and dry etch methods. Dry etch methods are generally more common since they provide generally straight sidewalls to the passivation layer 22′. Certain wet chemical etch methods are not excluded.

Subsequent to patterning the passivation layer 22 to yield the passivation layer 22′, the contact studs 24 are then located and formed into the contact vias. The contact studs 24 may comprise any of several conductor materials. Included, but not limiting, are metals, metal alloys, doped polysilicon and polycide contact stud materials. Particular metals include tungsten, copper and aluminum metals, but the foregoing selections do not limit the invention. Tungsten metal is particularly common as a contact stud material. The contact studs 24 may be formed using methods that are conventional in the semiconductor fabrication art. Included, but not limiting, are plating methods, chemical vapor deposition methods and physical vapor deposition methods.

FIG. 3 finally shows a passivation layer 26. The passivation layer 26 may comprise materials and be formed using methods that are used for forming the passivation layer 22. Thus, the passivation layer 26 may comprise oxides, nitrides and oxynitrides of silicon, as well as composites thereof and laminates thereof. Oxides, nitrides and oxynitrides of other elements are not excluded. Typically, the passivation layer 26 has a thickness from about 2000 to about 4000 angstroms.

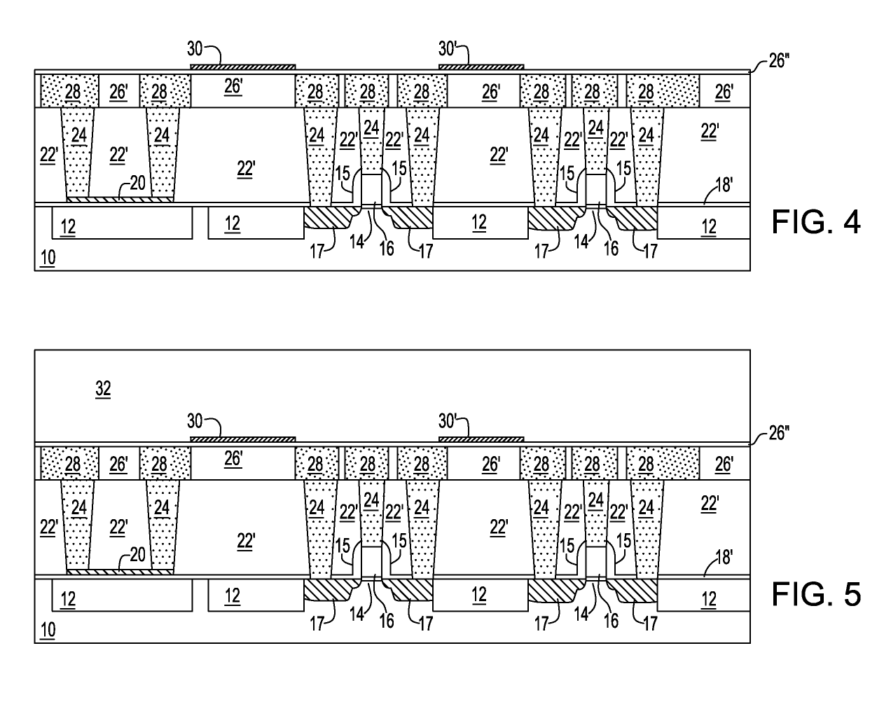

FIG. 4 first shows the results of patterning the passivation layer 26 to form passivation layer 26′. Located within passivation layer 26′ are interconnect layers 28. Passivation layer 26 may be patterned to form passivation layer 26′ while using photolithographic and etch methods that are conventional in the semiconductor fabrication art. Interconnect layers 28 may in general comprise the same materials that are used for forming the contact studs 24, with the exception that while tungsten is a common contact stud material, tungsten is not generally used as an interconnect material. Typically, the passivation layer 26′ has a thickness from about 2000 to about 4000 angstroms.

FIG. 4 finally shows resistors 30 and 30′ located upon passivation layer 26″, of which resistor 30 is intended as a component within a resistor structure in accordance with the invention. Passivation layer 26″ is comprised of a material similar to 26′. Resistors 30 and 30′ may comprise any of several resistor materials which are amenable to carrying a high current density. Non-limiting examples of such resistor materials include titanium, titanium nitride, tantalum, tantalum nitride, tungsten and tungsten nitride resistive materials. Typically the resistors 30 and 30′ have a thickness from about 200 to about 800 angstroms, an intended via to via linewidth from about 0.5 to about 50 microns, and a lateral (i.e., in and out of plane) linewidth from about 0.5 to about 50 microns. The resistors 30 and 30′ may be formed using any of several methods. Non-limiting examples include plating methods, chemical vapor deposition methods (including atomic layer chemical vapor deposition methods) and physical vapor deposition methods (including sputtering methods). Typically, the resistors 30 and 30′ comprises a nitride resistive material selected from the above group of resistive materials.

FIG. 5 shows passivation layer 32 located upon the semiconductor structure of FIG. 4. The passivation layer 32 may comprise a passivation material and be formed using a method that is analogous, equivalent or identical to the material and method that are used for forming the passivation layers 22′ and 26′. Typically, the passivation layer 32 has a thickness from about 4000 to about 7000 angstroms.

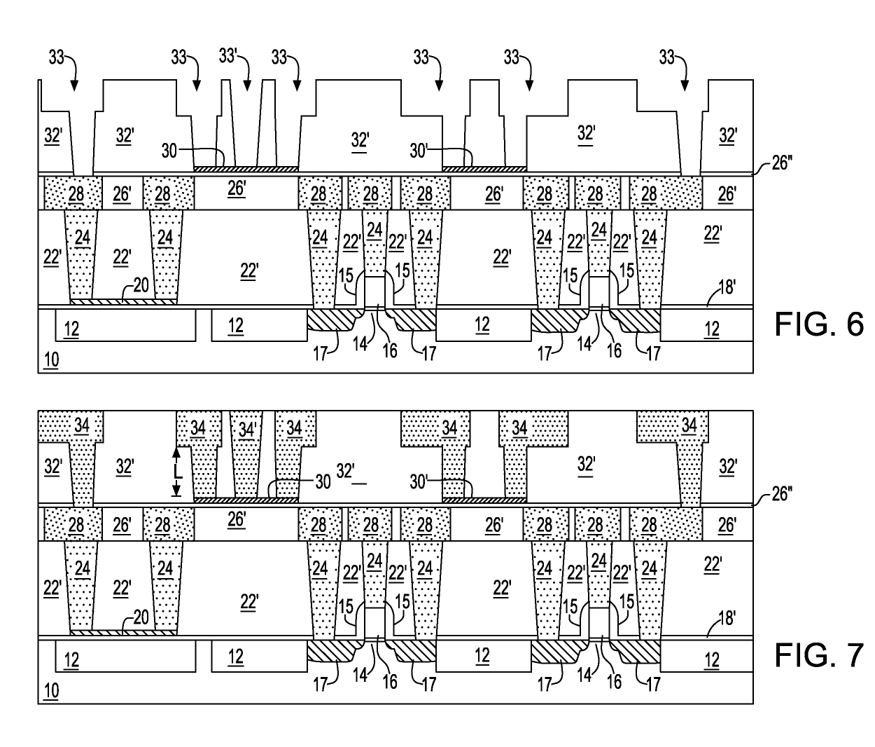

FIG. 6 shows dual damascene apertures 33 located within passivation layer 32′. The dual damascene apertures 33 may be formed using methods that are conventional in the semiconductor fabrication art. Typically, the dual damascene apertures 33 are intended to accommodate both conductor stud layers and contiguous conductor interconnect layers. Thus, the dual damascene apertures 33 comprise lower lying via portions connected to upper lying trench portions. Also shown in FIG. 6 is a nominally single damascene aperture 33′ that exposes a center portion of one of the resistor 30 (and in accord with disclosure below is intended to accommodate contact of the resistor by a heat sink layer). The dual damascene apertures 33 and the single damascene aperture 33′ may be formed using methods that are conventional in the semiconductor fabrication art. Options for the methods may include forming vias first and then trenches, as well as forming trenches first and then vias.

FIG. 7 shows stud/interconnect layers 34 that are located to fill dual damascene apertures 33 that are illustrated in FIG. 6. The stud/interconnect layers 34 (and additional stud/interconnect layers within the instant and additional embodiments) are intended as conductor contact layers with respect to resistor 30 within the context of the claimed invention. FIG. 7 also shows heat sink layer 34′ located within single damascene aperture 33′. The stud/interconnect layers 34 and the heat sink layer 34′ comprise a conductor material. Non-limiting examples of suitable conductor materials include copper conductor materials, aluminum conductor materials and tungsten conductor materials. The stud/interconnect layers 34 and heat sink layer 34′ are typically formed using a blanket layer deposition and subsequent planarization method that provides the stud/interconnect layers 34 located within the dual damascene apertures 33 and the heat sink layer 34′ located within the single damascene aperture 33′.

Within the instant embodiment, dimensions of the dual damascene apertures 33 (and the resulting stud/interconnect layers 34) are selected such that advantages of a Blech effect (i.e., a short length effect for electromigration inhibition) can be utilized when an electrical current passes through the stud/interconnect layers 34 and subsequently the resistor 30. A Blech effect is defined within the context of a Blech constant C for a particular conductor material (i.e., the Blech constant is a conductor material specific constant below which electromigration does not occur). To utilize a Blech constant C within the context of electromigration inhibition considerations, one determines the product of J×L, where J equals a current density through a conductor material of interest and L equals an interconnect length of the conductor material of interest. When the product of J×L exceeds the Blech constant C for the material of interest, electromigration of the conductor material occurs. For copper, a Blech constant C is typically about 300 mA/um. Blech constants will vary with material properties (both conductor itself and the surrounding insulator).

Thus, within the context of the instant embodiment, in order to take advantage of Blech effect for the stud/interconnect layers 34 (i.e., an electromigration effect), a stud length L within the stud/interconnect layer 34 as illustrated in FIG. 7 is preferably in a range of less than about 20 microns when the stud portion (or aggregate of stud portions) has a current carrying capacity (or demand) of about 15 mA/um². Upper lying interconnect portions of the stud/interconnect layers 34 (i.e., second stud/interconnect layers) generally have a greater plan-view area in comparison with stud portions, and thus may not necessarily be limited by current density constraints within the instant embodiment.

Also, within the instant embodiment the heat sink layer 34′ is intended to alleviate overheating of the resistor 30 and thus provide a uniform and lower temperature profile of the resistor 30. Typically, the uniform and lower temperature profile assists in providing a stable resistance for the resistor 30. The uniform and lower temperature profile also assists in providing higher current carrying capacity for the stud/interconnect layers 34. For example, for stud/interconnect layers 34 comprising copper, a maximum normalized current density of the stud/interconnect layers decreases by about a factor of 4 for a temperature increase from about 90° C. to about 110° C.

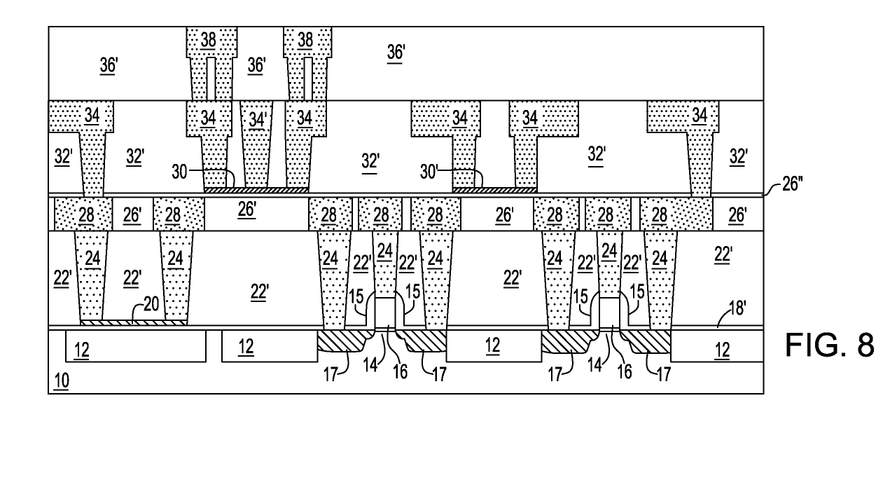

FIG. 8 shows a schematic cross-sectional diagram illustrating the results of further processing of the semiconductor structure of FIG. 7.

FIG. 8 shows passivation layers 36′ located upon passivation layers 32′. FIG. 8 also shows stud/interconnect layers 38 located contacting stud/interconnect layers 34.

The passivation layer 36′ may comprise materials, have dimensions and be formed using methods analogous, equivalent or identical to the materials, dimensions and methods used within the context of the underlying passivation layers 32′, 26′ and 22′. Similarly, the stud/interconnect layers 38 may also comprise materials, have dimensions and be formed using methods analogous, equivalent or identical to the materials, dimensions and methods used within the context of the stud/interconnect layers 34.

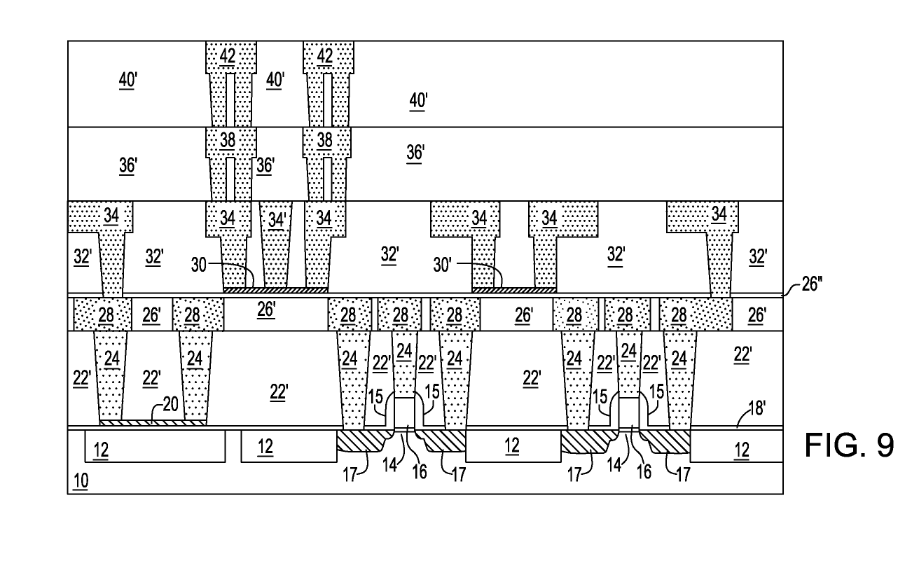

FIG. 9 shows a schematic cross-sectional diagram illustrating the results of further processing of the semiconductor structure whose schematic cross-sectional diagram is illustrated in FIG. 8.

FIG. 9 shows passivation layers 40′ located upon passivation layers 36′. FIG. 8 also shows stud/interconnect layers 42 located contacting stud/interconnect layers 38.

The passivation layer 40′ may comprise materials, have dimensions and be formed using methods analogous, equivalent or identical to the materials, dimensions and methods used within the context of the underlying passivation layers 36′, 32′, 26′ and 22′. Similarly, the stud/interconnect layers 42 may also comprise materials, have dimensions and be formed using methods analogous, equivalent or identical to the materials, dimensions and methods used within the context of the stud/interconnect layers 38 and 34.

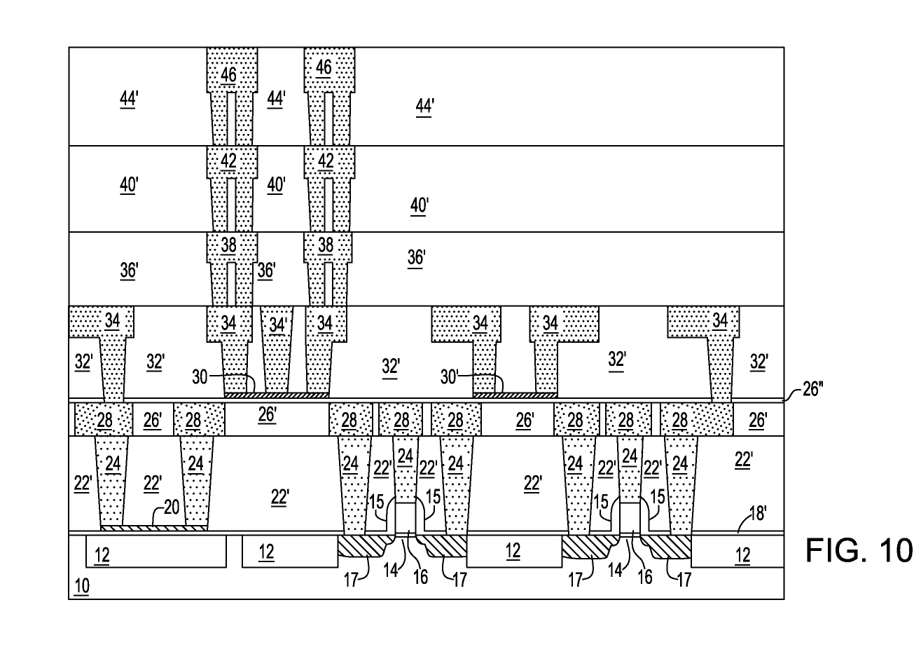

FIG. 10 shows a schematic cross-sectional diagram illustrating the results of further processing of the semiconductor structure of FIG. 9.

FIG. 10 shows passivation layers 44′ located upon passivation layers 36′. FIG. 10 also shows stud/interconnect layers 46 located contacting stud/interconnect layers 42.

The passivation layer 44′ may comprise materials, have dimensions and be formed using methods analogous, equivalent or identical to the materials, dimension and methods used within the context of the underlying passivation layers 40′, 36′, 32′, 26′ and 22′. Similarly, the stud/interconnect layers 46 may also comprise materials, have dimensions and be formed using methods analogous, equivalent or identical to the materials, dimensions and methods used within the context of the stud/interconnect layers 42, 38 and 34.

Within the context of the instant embodiment, and similarly with the stud/interconnect layers 34, each of the stud/interconnect layers 38, 42 and 46 is designed in size so that a Blech effect (i.e., an electromigration effect) within the stud interconnect layers 46, 42 and 38 may be avoided when power is supplied to the resistor 30. In addition, within the context of the instant embodiment, the stud/interconnect layers 46, 42, 38 and 34 are aligned vertically so that current flow is in a vertical only, until upper wiring levels (which are generally larger and have a linewidth from about 0.3 to about 1 microns), are reached. This vertical alignment of the stud/interconnect layers 46, 42, 38 and 34 also provides for enhanced heat dissipation from the resistor 30.

FIG. 10 shows a schematic cross-sectional diagram of a semiconductor structure in accordance with an embodiment of the invention. The semiconductor structure comprises a resistor 30 located over a substrate which comprises a semiconductor substrate 1O. The resistor 30 is intended as a high current density resistor. The resistor 30 is connected at both ends to other electrical circuit elements using stud/interconnect layers 34, 38, 42 and 46. The stud/interconnect layers 34, 38, 42, 46 are aligned vertically to provide a vertical current path. The stud/interconnect layers 34, 38, 42, 46 are also designed in dimension to take advantage of Blech effect (i.e., an electromigration effect) when the resistor is used within a circuit. The vertical alignment of the stud/interconnect layers 34, 38, 42 and 46 also provides for enhanced thermal dissipation within the semiconductor structure.

The embodiment also illustrates a heat sink layer 34′ located contacting the high current density resistor 30. The heat sink layer 34′ also assists in providing heat dissipation within the high current density resistor 30.

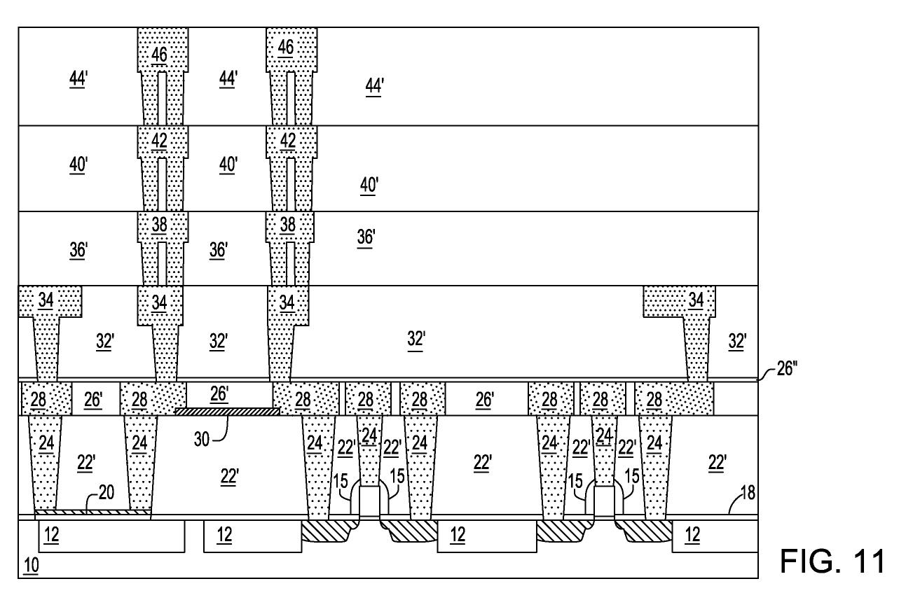

FIG. 11 shows a schematic cross-sectional diagram illustrating a semiconductor structure in accordance with another embodiment of the invention. This other embodiment of the invention comprises a second embodiment of the invention.

FIG. 11 shows a schematic cross-sectional diagram of a semiconductor structure largely analogous with the semiconductor structure of FIG. 10, but wherein the resistor 30 is located beneath the passivation layer 26′ rather than atop the passivation layer 26′. Contact to the resistor 30 is effected through interconnect layers 28 that in turn contact stud/interconnect layers 34, rather than through stud/interconnect layer 34 directly. Thus, the semiconductor structure that is illustrated in FIG. 1 functions differently from the semiconductor structure that is illustrated in FIG. 10.

The preferred embodiments of the invention are illustrative of the invention rather than limiting of the invention. Revisions and modifications may be made to methods, materials, structures and dimensions of a microelectronic structure in accordance with the preferred embodiments of the invention, while still providing a microelectronic structure in accordance with the invention, further in accordance with the accompanying claims.

What is claimed is:

1. A microelectronic structure comprising:
a resistor located over a substrate; and
a conductor contact layer contacting the resistor, where a maximum length of the conductor contact layer is determined using a Blech constant to avoid electromigration of a conductor material that comprises the conductor contact layer.

2. The structure of claim 1 further comprising at least one additional conductor contact layer contacting the conductor contact layer, where the at least one additional conductor contact layer and the conductor contact layer are aligned vertically.

3. The structure of claim 1 further comprising a heat sink layer located contacting the resistor.

4. The structure of claim 1 wherein the resistor comprises a material selected from the group consisting of titanium, tungsten and tantalum, and nitrides of titanium, tungsten and tantalum.

5. The structure of claim 1 wherein the resistor has a thickness from about 200 to about 800 angstroms.

6. The structure of claim 1 wherein the resistor has a length from about 0.5 to about 50 microns.

7. The structure of claim 1 wherein the resistor has a width from about 0.5 to about 50 microns.

8. The structure of claim 1 wherein the substrate comprises a semiconductor substrate.

9. The structure of claim 1 wherein the conductor contact layer comprises a copper material.

10. The structure of claim 1 wherein the conductor contact layer comprises a tungsten material.

11. The structure of claim 1 wherein the conductor contact layer comprises an aluminum material.

12. The structure of claim 1 wherein the conductor contact layer comprises an interconnect layer within a semiconductor structure.

13. The structure of claim 1 wherein the conductor contact layer comprises a stud/interconnect layer within a semiconductor structure.

14. A method for fabricating a microelectronic structure comprising:
forming a resistor located over a substrate; and
forming a conductor contact layer contacting the resistor, wherein when forming the conductor contact layer a maximum length of the conductor contact layer is determined using a Blech constant to avoid electromigration of a conductor material that comprises the conductor contact layer.

15. The method of claim 14 further comprising forming a heat sink layer contacting the resistor.

16. The method of claim 14 further comprising forming an additional conductor contact layer vertically aligned upon the conductor contact layer.

17. The method of claim 14 wherein the forming the resistor uses a material selected from the group consisting of titanium, tungsten and tantalum, and nitrides of titanium, tungsten and tantalum.

18. The method of claim 14 wherein the forming the conductor contact layer uses a copper conductor material.

19. The method of claim 14 wherein the forming the conductor contact layer uses a tungsten conductor material.

20. The method of claim 14 wherein the forming the conductor contact layer uses an aluminum conductor material.
